(19) United States
(12) Patent Application Publication
(10) Pub. No.: US 2003/0045119 A1
(43) Pub. Date: Mar. 6, 2003

(54) Method for forming a bottle-shaped trench

(76) Inventors: Hsiao-Lei Wang, Tainan (TW); Chao-Hsi Chung, Jubei City (TW); Hung-Kwei Liao, Lungtan Shiang (TW); Chao-Chueh Wu, Shinpu Jen (TW)

Correspondence Address: SNELL & WILMER, ONE ARIZONA CENTER, 400 EAST VAN BUREN, PHOENIX, AZ, 850040001

(21) Appl. No.: 09/947,856

(22) Filed: Sep. 6, 2001

(51) Int. Cl. H01L 21/302; H01L 21/461

(52) U.S. Cl. 438/745

(57) ABSTRACT

The present invention provides a method for forming a bottle-shaped trench in a semiconductor substrate. The method shields the circumferential wall of the section of a first depth of a trench with a collar, and expands the cross sectional area of the section of a second depth of the trench by using a wet etchant. A bottle-shaped trench in a semiconductor substrate is then formed.

### FIELD OF THE INVENTION

The present invention relates to the formation of a trench, and especially to a bottle-shaped trench formation in a semiconductor substrate.

### BACKGROUND OF THE INVENTION

A Dynamic Random Access Memory (DRAM) includes arrays, composed of multiple memory cells. Cells are accessed by the wordline and bitline. Reading or writing data from/to the memory cells is performed by activating an appropriate wordline or bitline.

Usually the memory cell of a DRAM includes a transistor connecting to a capacitor. The transistor has two diffusion areas with a channel, and the channel is between the two diffusion areas. Above the channel is a gate. Depending on the direction of the current, the two diffusion areas are respectively either the source or the drain. The gate is connected to the wordline, and two diffusion areas are connected to the bitline and the capacitor respectively. When applying an appropriate voltage to the gate to switch the transistor “ON”, a current is flowing through channel to connect the bitline and the capacitor. When the transistor is “OFF”, no current flows between the bitline and capacitor.

As the integration density of DRAM increases, the memory cell size has to shrink correspondingly while maintaining the minimum required storage capacitance of the DRAM. The memory cell size is limited by the resolution of a lithography technique used, the overlay tolerance of different features and the layout. To meet the requirements, a trench capacitor was proposed. In the premise that the memory cell size is small, enlarging the dimension of the trench in the vertical direction allows the increase of surface area of the capacitor and, therefore, the increase of the capacity of the capacitor (capacitance).

The trench capacitor is formed on a silicon substrate, and the vertical circumferential wall of the trench capacitor is used to store the charge. The trench is filled with n-doped polysilicon acting as an electrode of the capacitor and is called a storage node. Afterwards an n-doped area is formed on a lower circumferential wall of the trench acting as another electrode which is called a buried plate. A dielectric is provided between the storage node and buried plate to separate one from each other, and the dielectric is called a node dielectric.

The methods for forming the buried plate is formed a conductive region by diffusing a dopant or by performing an epitaxy in the lower circumferential wall. The dopant usually is n-doped silicate glass, such as arsenic silicate glass (ASG). The buried plate also can be formed by a gas phase doping (GPD) technology, which is well known in the arts.

When the memory cell size shrinks to meet market demand, adoption of the circumferential wall perpendicular to the substrate alone can not achieve the adequate capacitance. For enhancing the surface area of the trench and capacitance, a bottle-shaped trench with larger cross-sectional area in the lower portion thereof was disclosed.

There are several methods of prior arts for fabricating a bottle-shaped trench. U.S. Pat. No. 5,891,807 issued to K. Paul Muller et al. entitled “Formation of a Bottle shaped Trench” discloses forming a tapered positively sloped top portion at a first temperature and then a tapered negatively sloped bottom portion at a second temperature to fabricate a bottle shaped trench in a semiconductor substrate. Nevertheless, it is found that this method often can not enlarge the difference of the cross-sectional areas between the top and bottom portions of the trench efficiently.

U.S. Pat. No. 5,658,816 issued to Thekkemadathil Velayudhan Rajeevakumar entitled “Method of Making DRAM Cell with Trench under Device for 256 MB DRAM and Beyond” discloses another method for fabricating the bottle-shaped trench. A trench, having the first depth and a first cross sectional area, is formed by etching a substrate, and, afterwards, a collar is formed on the wall of the trench to protect the trench wall. The depth of the trench is increased to a second depth and an oxide layer is formed on the trench wall which is not protected by the collar. The oxide layer is removed by diluted hydrofluoric acid and the cross-sectional area of the unprotected wall is expanded to a second cross-sectional area because of the removal of the oxide layer. The diameter of the trench is narrow on top and wide on bottom since the second cross-sectional area is larger than the first cross-sectional area. This method needs to expose the semiconductor device to a high temperature and will affects the performance stability of the device. Additionally, the material of the collar is nitride which is same as the material of the protective layer on the substrate. Therefore, in the succeeding processes, this method can not provide a processing step which will etch collar without etching the protective layer, and vice versa.

Additionally, in U.S. Pat. No. 6,190,988 issued to Toshiharu et al. entitled “Method for a Controlled Bottle Trench for a DRAM Storage Node”, another method is disclosed. The method has a collar to protect the top portion of the trench, and an impurity diffusion region formed in the lower portion of the side wall. An isotropic wet etch is performed to remove the impurity diffusion region. The wet etch degree of this patent is controlled by dopant diffusion. Before enlarging the lower portion of the trench, the steps of deposing the dopant, thermally driving the dopant into the wall and removing redundant dopant are required.

As recited above, the prior arts involve many steps and many thermal processes, and are not cost effective. There is a need for a novel approach to make a bottled-shaped trench capacitor.

### SUMMARY OF THE INVENTION

The objective of the present invention is to provide a more effective method with fewer steps for forming a bottle-shaped trench on a substrate.

The method of the present invention includes the step of forming a trench with the first depth region having an open end, and the open end has a first cross-sectional area and a first circumferential wall on the surface of the substrate. Afterwards, the invention forms a collar on the first circumferential wall of the first depth region to protect the first circumferential wall. Afterwards, the invention etches the trench to form the second depth region. Afterwards, the invention performs a wet etch to expand the cross-sectional area of the second depth region to a second cross-sectional area, the second cross-sectional area defines a second circumferential wall on the second depth region. Finally, the invention forms a dopant diffusion region in the second circumferential wall of the second depth region.

The method further includes the steps of forming a dielectric on the second circumferential wall of the second depth region and forming a conductive region in the trench.

The steps for forming the dopant diffusion region further includes the step of driving a dopant in the second circumferential wall of the second depth region by gas phase doping. These steps alternatively includes forming a silicate glass doped by a dopant in the second circumferential wall of the second depth region and then driving the dopant in said second circumferential wall of the second depth region. Finally, to remove the silicate glass doped by the dopant.

The steps for forming the conductive region further include filling the trench with polysilicon, and etching back polysilicon in the trench to a predetermined depth.

Persons skilled in the art will understand the objectives and advantages of the present invention after reading the detail description of the embodiments with diagrams states as follows.

### BRIEF DESCRIPTION OF THE DRAWINGS

FIG. 1 is a schematic diagram showing that a protective layer and a hard mask are deposited on a substrate.

FIG. 2 is a schematic diagram showing that the pattern of the hard mask on the substrate is completed.

FIG. 3 is a schematic diagram after the first depth region is etched in the substrate.

FIG. 4 is a schematic diagram showing that the collar is formed on the first circumferential wall of the first depth region.

FIG. 5 is a schematic diagram showing that the second depth region is etched in the substrate.

FIG. 6 is a schematic diagram after the cross-sectional area of the second depth region is expanded.

FIG. 7a is a schematic diagram showing after a silicate glass doped by a dopant is deposited.

FIG. 7b is a schematic diagram after the dopant diffusion region is formed.

FIG. 8 is a schematic diagram that a dielectric is formed on the second circumferential wall of the second depth region.

FIG. 9 is a schematic diagram that the bottle-shaped trench is filled with polysilicon.

FIG. 10 is a diagram drawing that the conductive region is formed by etching back polysilicon.

### DETAILED DESCRIPTION OF THE INVENTION

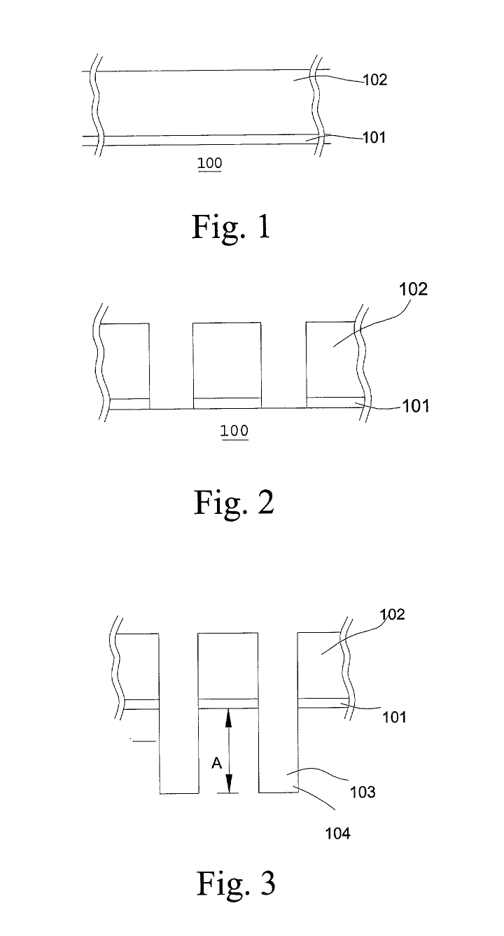

Please refer to FIG. 1, a protective layer 101 composed of silicon nitride is on a substrate 100, and a hard mask 102 without pattern is on the protective layer 101.

After the patterns of the hard mask 102 and protective layer 101 are finished, as shows in FIG. 2, an anisotropic dry etch is performed to form the first depth region 103 with a depth A measured from the bottom of the protective layer 101, as shows in FIG. 3.

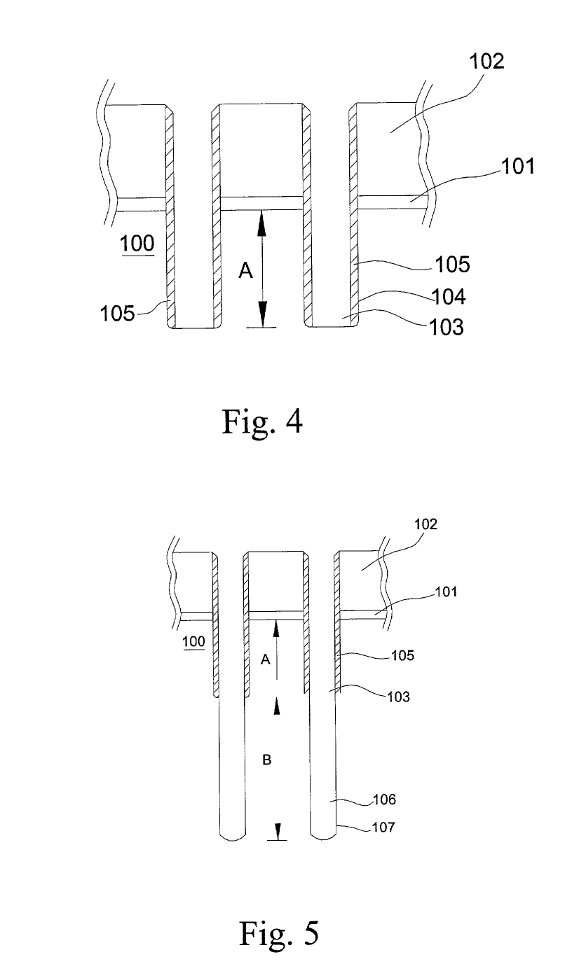

Referring to FIG. 4, a collar 105 is formed on the first circumferential wall 104 of the first depth region 103. The collar 105 is preferably made from silicon oxide. The steps of forming the collar 105 include depositing a silicon oxide over the hard mask 102 and the first circumferential wall 104, and performing an anisotropic dry etch to remove the silicon oxide layer in the horizontal direction. The silicon oxide layers in the horizontal direction are layers respectively on the surface of the hard mask 102 and the bottom of the trench. Because of the anisotropic etch, the silicon oxide layer on the first circumferential wall 104 remains to form a collar 105 around the circumferential wall 104.

Following the collar 105 formation, another anisotropic etch is performed to deepen the trench to a depth of (A+B) measured from the bottom of the protective layer 101, as shown in FIG. 5. At this stage, the first circumferential wall 104 is protected by the collar 105, but the circumferential wall 107 of the second depth region 106 is exposed.

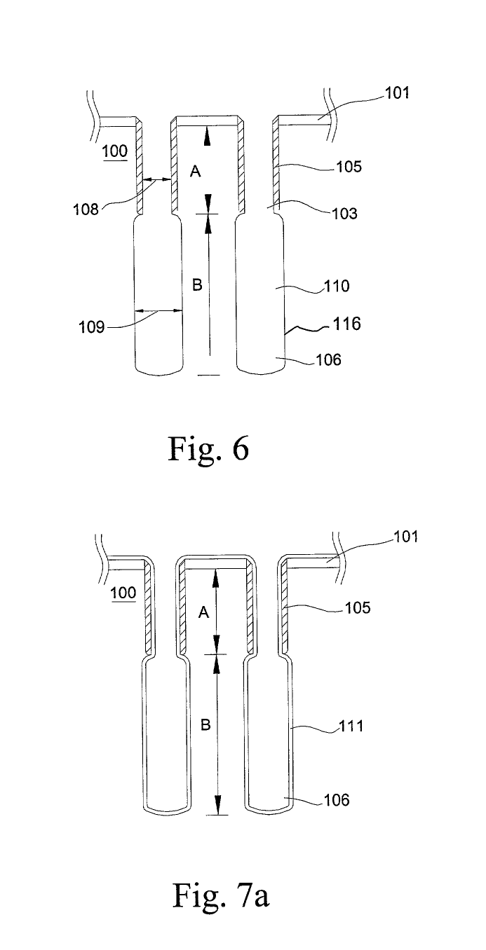

Referring to FIG. 6, the steps following include removing the hard mask 102 and performing a wet etch with an etchant to expand the cross-sectional area of the second depth region 106 to form the second circumferential wall 116. Now the first depth region 103 has the first cross-sectional area 108, and the second depth region 106 has the second cross-sectional area 109. The second cross-sectional area 109 is larger than the first cross-sectional area 108. The shape of the bottle-shaped trench 110 is finally formed and the cross-sectional area of the first depth region 103 is smaller than that of the second depth region 106.

The etchant of the present invention is a solution containing hydrogen peroxide (H₂O₂) and ammonium hydroxide (NH₄OH). This solution has high selectivity to silicon and the etching rate to the silicon oxide is very slow. Therefore the collar 105 can protect the first circumferential wall 104 from etching and the exposed circumferential wall 107 is etched by the solution to expand the second cross-sectional area 109.

When the bottle-shaped trench 110 is used in the DRAM, there must have a dopant diffusion region to form a conductive buried plate. Two methods for forming the dopant diffusion region are described as follows.

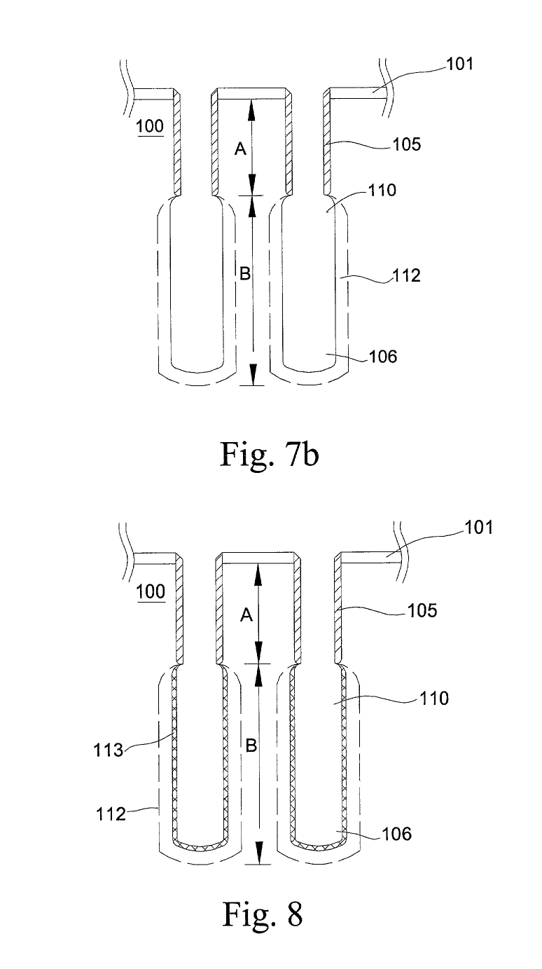

In one embodiment, the silicate glass doped by a dopant, such as arsenic silicate glass, is deposited on the protective layer 101, the collar 105 and the circumferential wall 107, as shown in FIG. 7. The dopant is thermally driven into the circumferential wall 107 and then the doped silicate glass 111 is removed. At this stage, the bottle-shaped trench is shown in FIG. 7b, and the dopant diffusion region 112 is indicated by the dotted line.

In another embodiment, the dopant diffusion region 112 is formed by a gas phase doping approach. The gas phase doping approach involves introducing an adequate compound gas under a proper temperature and pressure, and the dopant diffusion region 112 is formed directly, as shown in FIG. 7b. The gas phase doping approach needs fewer steps and is more suitable for the fabrication process of the bottle-shaped trench.

Following the formation the dopant diffusion region 112, a dielectric 113 is formed as shown in FIG. 8. In a preferred embodiment, the dielectric 113 is oxynitride (NO). The formation steps include depositing a nitride layer on the second circumferential wall 107, and then applying an oxidation step to form the dielectric 113 composed of oxynitride.

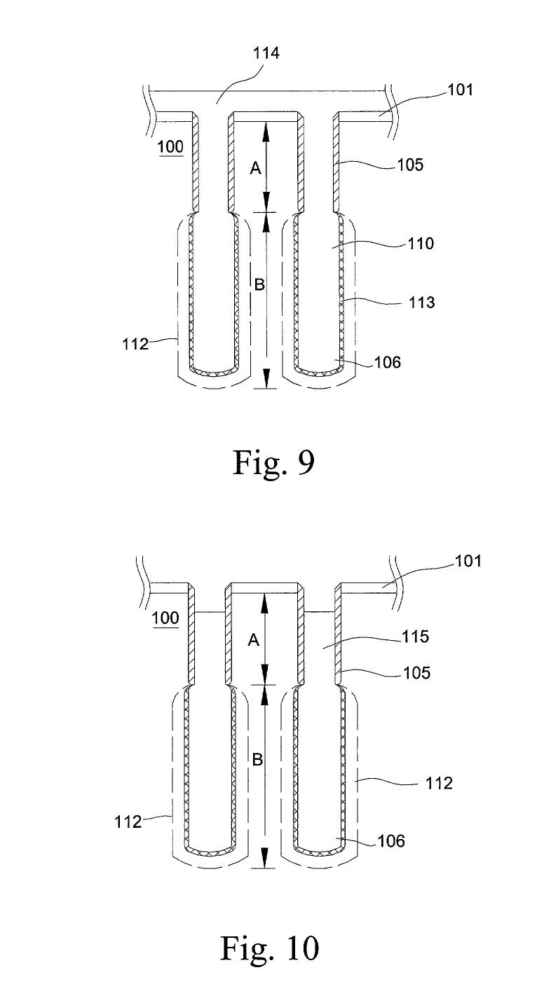

In order to form another electrode of the buried plate, a conductive region must be formed in the bottle-shaped trench. In typical, the material of the conductive region is polysilicon. Please refer to FIG. 9, a polysilicon 114 is deposited and filled into the bottle-shaped trench 110. The surface of the protective layer 101 is covered with the polysilicon 114. Afterwards, the etch-back operation is performed to the polysilicon 114 to a predetermined depth, and the conductive region 115 is formed. At this stage, the fundamental electrode-dielectric-electrode framework of the bottle-shaped trench is accomplished.

For the connection purpose of the bottle-shaped trench, portion of the collar 105 adjacent to the protective layer 101 must be removed. In the above embodiment, the protective layer 101 is composed of silicon nitride while the collar 105 is composed of silicon oxide. Therefore, using the hydrofluoric acid only etches the portion of collar 105 and substantially keeps the integrity of the protective layer 101 and the conductive region 115.

It should be noted, although the embodiment of the present invention is introduced under the technical field of a DRAM, other semiconductor devices employing the bottle-shaped trench can also receive benefit from the present invention.

It should be appreciated by those skilled in the art that the present invention can be practiced in other specific ways without departing from the spirit and scope thereof, and therefore the provided embodiments here is illustrative but not restrictive. The scope of the invention should be determined not with reference to the above description but with reference with the appended claims with their full scope of equivalents.

What is claimed is:

1. A method for fabricating a bottle-shaped trench in a substrate, comprising the steps of:
forming a trench having a first depth region, said first depth region having an open end on the surface of said substrate, and said open end having a first cross-sectional area and a first circumferential wall;
forming a collar on said first circumferential wall of said first depth region to protect said first circumferential wall;
etching said trench to form a second depth region;
performing a wet etch to expand the cross-sectional area of said second depth region to a second cross-sectional area by using an etchant, said second cross-sectional area defining a second circumferential wall on the second depth region; and
forming a dopant diffusion region in said second circumferential wall of said second depth region.

2. The method of claim 1 further comprising the steps of:
forming a dielectric on said second circumferential wall of said second depth region; and
forming a conductive region in said trench.

3. The method of claim 1, wherein said etchant is a solution containing hydrogen peroxide (H₂O₂) and ammonium hydroxide (NH₄OH.).

4. The method of claim 1, wherein the step of forming said dopant diffusion region further comprises the step of:
doping a dopant in said second circumferential wall of said second depth region by gas phase doping.

5. The method of claim 1, wherein the step of forming said dopant diffusion region further comprises the steps of:
forming a silicate glass doped by a dopant in said second circumferential wall of said second depth region;
driving said dopant into said second circumferential wall of said second depth region; and
removing said silicate glass doped by said dopant.

6. The method of claim 2, wherein the step of forming said conductive region comprises the steps of:
filling said trench with polysilicon; and
etching back said polysilicon material in said trench to a predetermined depth.

7. The method of claim 2, wherein said dielectric is made of oxynitride (NO).
